(19) United States
(12) Patent Application Publication
(10) Pub. No.: US 2024/0425975 A1
(43) Pub. Date: Dec. 26, 2024

(54) THIN-FILM FORMING RAW MATERIAL, METHOD OF PRODUCING THIN-FILM, THIN-FILM, AND MOLYBDENUM COMPOUND

(71) Applicant: ADEKA CORPORATION, Tokyo (JP)

(72) Inventors: Masako HATASE, Tokyo (JP); Keisuke TAKEDA, Tokyo (JP); Chiaki MITSUI, Tokyo (JP)

(73) Assignee: ADEKA CORPORATION, Tokyo (JP)

(21) Appl. No.: 18/695,108

(22) PCT Filed: Sep. 20, 2022
(86) PCT No.: PCT/JP2022/035000

§ 371 Date: Mar. 25, 2024

(30) Foreign Application Priority Data
Oct. 1, 2021 (JP) 2021-162907

(51) Int. Cl. C23C 16/18; C07F 11/00; C23C 16/44; C23C 16/448; C23C 16/455

(52) U.S. Cl. CPC C23C 16/18; C07F 11/005; C23C 16/4408; C23C 16/4485; C23C 16/45553

(57) ABSTRACT

A thin-film forming raw material contains a molybdenum compound represented by the following general formula (1), a method of forming a thin-film through use of the thin-film forming raw material, and a molybdenum compound having a specific structure:

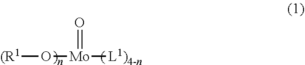

where R¹ represents an alkyl group having 1 to 5 carbon atoms or a fluorine atom-containing alkyl group having 1 to 5 carbon atoms, L¹ represents a group represented by the following general formula (L-1) or (L-2), and “n” represents an integer of from 1 to 4, provided that when “n” represents 4, R¹ represents a fluorine atom-containing alkyl group having 1 to 5 carbon atoms;

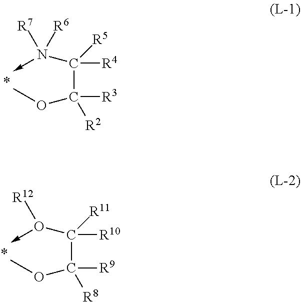

where R² to R¹² each independently represent a hydrogen atom, an alkyl group having 1 to 5 carbon atoms, or a fluorine atom-containing alkyl group having 1 to 5 carbon atoms, and * represents a bonding site.

### TECHNICAL FIELD

The present invention relates to a thin-film forming raw material containing a molybdenum compound having a specific structure, a method of producing a thin-film, a thin-film, and a molybdenum compound.

### BACKGROUND ART

It has been known that thin-films containing molybdenum atoms can be used for electronic devices, semiconductor devices, liquid crystal members, coating materials, heat-resistant materials, alloys, aircraft members, or the like.

Examples of a method of producing the above-mentioned thin-film include: a sputtering method; an ion plating method; MOD methods, such as a coating thermal decomposition method and a sol-gel method; and a chemical vapor deposition method. Of those, a chemical vapor deposition (hereinafter sometimes simply referred to as “CVD”) method including an atomic layer deposition (hereinafter sometimes simply referred to as “ALD”) method is an optimum production process because the method has many advantages, such as excellent composition controllability and step coverage, suitability for mass production, and capability of hybrid integration.

Various raw materials have been frequently reported as molybdenum atom supply sources to be used in the chemical vapor deposition method. For example, in Patent Document 1, there are disclosures of molybdenum-oxo-tetra (sec-butoxide) and molybdenum-oxo-tetra (tert-butoxide). In addition, in Patent Documents 2 and 3, there are disclosures of bis(tert-butylimido)-bis(dimethylamido)molybdenum and bis(tert-butylimido)-bis(diethylamido)molybdenum.

### CITATION LIST

### Patent Document

[Patent Document 1] JP 2017-532385 A
[Patent Document 2] JP 2016-516892 A
[Patent Document 3] JP 2018-150627 A

### SUMMARY OF INVENTION

### Technical Problem

In a method including vaporizing a compound to form a thin-film such as the CVD method, an important property required for a compound (precursor) to be used as a thin-film forming raw material is to be able to produce a high-quality thin-film. However, the related-art molybdenum compound, which has been used as the thin-film forming raw material, has not been sufficiently satisfactory in terms of this property.

Accordingly, an object of the present invention is to provide a molybdenum compound, which can produce a high-quality thin-film when used as a thin-film forming raw material.

### Solution to Problem

The inventors of the present invention have made investigations, and as a result, have found that a molybdenum compound having a specific structure can solve the above-mentioned problem. Thus, the inventors have reached the present invention.

That is, according to an embodiment of the present invention, there is provided a thin-film forming raw material containing a molybdenum compound represented by the following general formula (1):

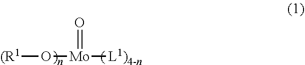

where R¹ represents an alkyl group having 1 to 5 carbon atoms or a fluorine atom-containing alkyl group having 1 to 5 carbon atoms, L¹ represents a group represented by the following general formula (L-1) or (L-2), and “n” represents an integer of from 1 to 4, provided that when “n” represents 4, R¹ represents a fluorine atom-containing alkyl group having 1 to 5 carbon atoms;

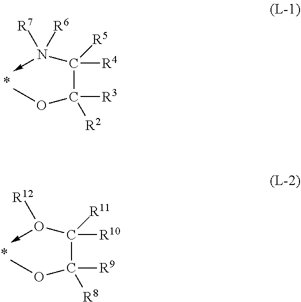

where R² to R¹² each independently represent a hydrogen atom, an alkyl group having 1 to 5 carbon atoms, or a fluorine atom-containing alkyl group having 1 to 5 carbon atoms, and * represents a bonding site.

According to another embodiment of the present invention, there is provided a method of producing a thin-film, comprising forming a thin-film containing a molybdenum atom on a surface of a substrate through use of the above-mentioned thin-film forming raw material.

According to still another embodiment of the present invention, there is provided a molybdenum-containing thin-film, which is produced by using the above-mentioned thin-film forming raw material.

According to still another embodiment of the present invention, there is provided a molybdenum compound, which is represented by the following general formula (2):

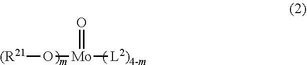

where R²¹ represents an alkyl group having 1 to 5 carbon atoms or a fluorine atom-containing alkyl group having 1 to 5 carbon atoms, L² represents a group represented by the following general formula (L-3) or (L-4), and “m” represents an integer of from 1 to 4, provided that when “m” represents 4, R²¹ represents a fluorine atom-containing alkyl group having 1 to 5 carbon atoms and having 1 to 8 fluorine atoms;

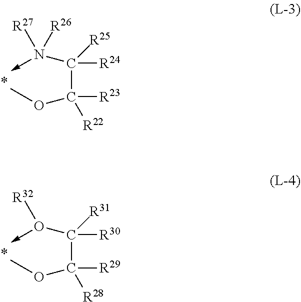

where R²² to R³² each independently represent a hydrogen atom, an alkyl group having 1 to 5 carbon atoms, or a fluorine atom-containing alkyl group having 1 to 5 carbon atoms, and * represents a bonding site.

### Advantageous Effects of Invention

According to the present invention, the thin-film forming raw material, which can produce a thin-film containing a molybdenum atom, can be provided. In addition, according to the present invention, the method of producing a high-quality thin-film containing a molybdenum atom can be provided.

### BRIEF DESCRIPTION OF DRAWINGS

FIG. 1 is a schematic diagram for illustrating an example of an ALD apparatus to be used in a method of producing a thin-film according to the present invention.

FIG. 2 is a schematic diagram for illustrating another example of the ALD apparatus to be used in the method of producing a thin-film according to the present invention.

FIG. 3 is a schematic diagram for illustrating still another example of the ALD apparatus to be used in the method of producing a thin-film according to the present invention.

FIG. 4 is a schematic diagram for illustrating still another example of the ALD apparatus to be used in the method of producing a thin-film according to the present invention.

### DESCRIPTION OF EMBODIMENTS

A thin-film forming raw material of the present invention is characterized by containing a molybdenum compound represented by the general formula (1).

In the general formula (1), R¹ represents an alkyl group having 1 to 5 carbon atoms or a fluorine atom-containing alkyl group having 1 to 5 carbon atoms, L¹ represents a group represented by the general formula (L-1) or (L-2), and “n” represents an integer of from 1 to 4, provided that when “n” represents 4, R¹ represents a fluorine atom-containing alkyl group having 1 to 5 carbon atoms.

In the general formulae (L-1) and (L-2), R² to R¹² each independently represent a hydrogen atom, an alkyl group having 1 to 5 carbon atoms, or a fluorine atom-containing alkyl group having 1 to 5 carbon atoms, and * represents a bonding site.

Examples of the “alkyl group having 1 to 5 carbon atoms” include a methyl group, an ethyl group, a propyl group, an isopropyl group, a butyl group, an isobutyl group, a sec-butyl group, a tert-butyl group, a pentyl group, an isopentyl group, and a neopentyl group.

Examples of the “fluorine atom-containing alkyl group having 1 to 5 carbon atoms” include a monofluoromethyl group, a difluoromethyl group, a trifluoromethyl group, a trifluoroethyl group, a trifluoropropyl group, a dimethyltrifluoroethyl group, a (trifluoromethyl)tetrafluoroethyl group, a hexafluoro-tert-butyl group, a di-(trifluoromethyl)ethyl group, and a nonafluoro-tert-butyl group.

In the general formulae (1), (L-1), and (L-2), R¹ to R¹², L¹, and “n” are appropriately selected in accordance with a method of producing a thin-film to be applied. When the thin-film forming raw material of the present invention is used in a method of producing a thin-film comprising a step of vaporizing a compound, R¹ to R¹², L¹, and “n” are preferably selected so that the compound may have at least one property selected from a high vapor pressure, a low melting point, and high thermal stability, and R¹ to R¹², L¹, and “n” are more preferably selected so that the compound may have high thermal stability.

R¹ preferably represents an alkyl group having 2 to 4 carbon atoms or a fluorine atom-containing alkyl group having 2 to 4 carbon atoms because the compound has high thermal stability, and can produce a high-quality thin-film with high productivity when used as a thin-film forming raw material. More specifically, when “n” represents 1 to 3, R¹ represents preferably an alkyl group having 3 or 4 carbon atoms, more preferably a sec-butyl group or a tert-butyl group, particularly preferably a tert-butyl group, and when “n” represents 4, R¹ represents preferably a fluorine atom-containing alkyl group having 3 or 4 carbon atoms, more preferably a fluorine atom-containing alkyl group having 4 carbon atoms, particularly preferably a dimethyltrifluoroethyl group, a di-(trifluoromethyl)ethyl group, or a nonafluoro-tert-butyl group, most preferably a dimethyltrifluoroethyl group. When R¹ represents a fluorine atom-containing alkyl group, R¹ has preferably 1 to 12 fluorine atoms, more preferably 1 to 8 fluorine atoms, particularly preferably 1 to 4 fluorine atoms, most preferably 3 fluorine atoms because the compound has high thermal stability, and can produce a high-quality thin-film with high productivity when used as a thin-film forming raw material.

L¹ preferably represents a group represented by the general formula (L-1) because the compound has a low melting point and high thermal stability, and can produce a high-quality thin-film with high productivity when used as a thin-film forming raw material. “n” represents preferably 3 or 4, more preferably 4 because the compound has high thermal stability, and can produce a high-quality thin-film with high productivity when used as a thin-film forming raw material.

R² represents preferably a hydrogen atom or an alkyl group having 1 to 5 carbon atoms, more preferably an alkyl group having 1 to 5 carbon atoms, still more preferably an alkyl group having 1 to 3 carbon atoms, particularly preferably a methyl group because the compound has a high vapor pressure, and can produce a high-quality thin-film with high productivity when used as a thin-film forming raw material. R³ represents preferably a hydrogen atom or an alkyl group having 1 to 5 carbon atoms, more preferably a hydrogen atom or an alkyl group having 1 to 3 carbon atoms, still more preferably a hydrogen atom or a methyl group, particularly preferably a hydrogen atom because the compound has a high vapor pressure, and can produce a high-quality thin-film with high productivity when used as a thin-film forming raw material. R⁴ and R⁵ each independently represent preferably a hydrogen atom or an alkyl group having 1 to 5 carbon atoms, more preferably a hydrogen atom or an alkyl group having 1 to 3 carbon atoms, particularly preferably a hydrogen atom because the compound has a high vapor pressure, and can produce a high-quality thin-film with high productivity when used as a thin-film forming raw material. R⁶ and R⁷ each independently represent preferably a hydrogen atom or an alkyl group having 1 to 5 carbon atoms, more preferably an alkyl group having 1 to 5 carbon atoms, still more preferably an alkyl group having 1 to 3 carbon atoms, particularly preferably a methyl group because the compound has a high vapor pressure and high thermal stability, and can produce a high-quality thin-film with high productivity when used as a thin-film forming raw material.

R⁸ represents preferably a hydrogen atom or an alkyl group having 1 to 5 carbon atoms, more preferably an alkyl group having 1 to 5 carbon atoms, still more preferably an alkyl group having 1 to 3 carbon atoms, particularly preferably a methyl group because the compound has a high vapor pressure, and can produce a high-quality thin-film with high productivity when used as a thin-film forming raw material. R⁹ represents preferably a hydrogen atom or an alkyl group having 1 to 5 carbon atoms, more preferably a hydrogen atom or an alkyl group having 1 to 3 carbon atoms, still more preferably a hydrogen atom or a methyl group, particularly preferably a methyl group because the compound has a high vapor pressure, and can produce a high-quality thin-film with high productivity when used as a thin-film forming raw material. R¹⁰ and R¹¹ each independently represent preferably a hydrogen atom or an alkyl group having 1 to 5 carbon atoms, more preferably a hydrogen atom or an alkyl group having 1 to 3 carbon atoms, particularly preferably a hydrogen atom because the compound has a high vapor pressure, and can produce a high-quality thin-film with high productivity when used as a thin-film forming raw material. R¹² represents preferably a hydrogen atom or an alkyl group having 1 to 5 carbon atoms, more preferably an alkyl group having 1 to 5 carbon atoms, still more preferably an alkyl group having 1 to 3 carbon atoms, particularly preferably a methyl group because the compound has a high vapor pressure and high thermal stability, and can produce a high-quality thin-film with high productivity when used as a thin-film forming raw material.

In addition, when the molybdenum compound of the present invention is used in a method of producing a thin-film by a MOD method free of any vaporization step, R¹ to R¹², L¹, and “n” may be arbitrarily selected in accordance with, for example, the solubility of the compound in a solvent to be used and a thin-film formation reaction.

Preferred specific examples of the molybdenum compound represented by the general formula (1) include Compounds No. 1 to No. 120 below. In Compounds No. 1 to No. 120 below, “Me” represents a methyl group, “Et” represents an ethyl group, “iPr” represents an isopropyl group, “iBu” represents an isobutyl group, “sBu” represents a sec-butyl group, and “tBu” represents a tert-butyl group.

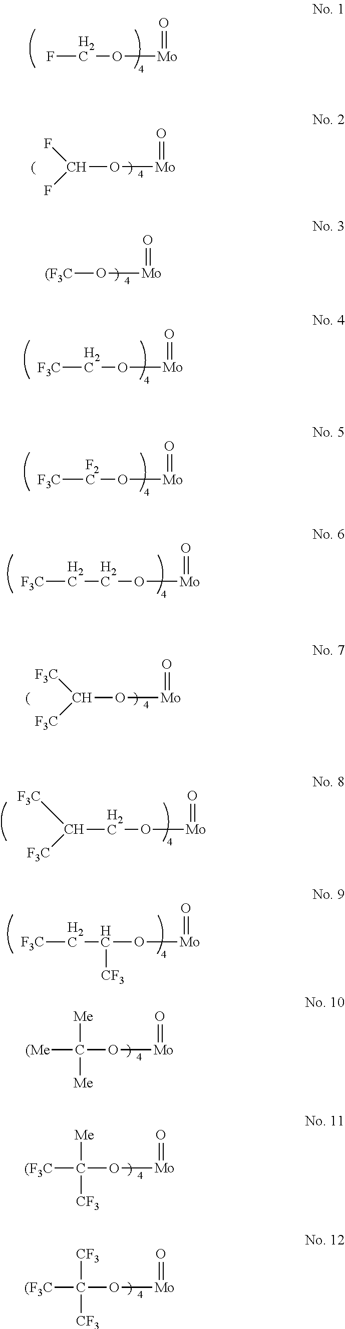

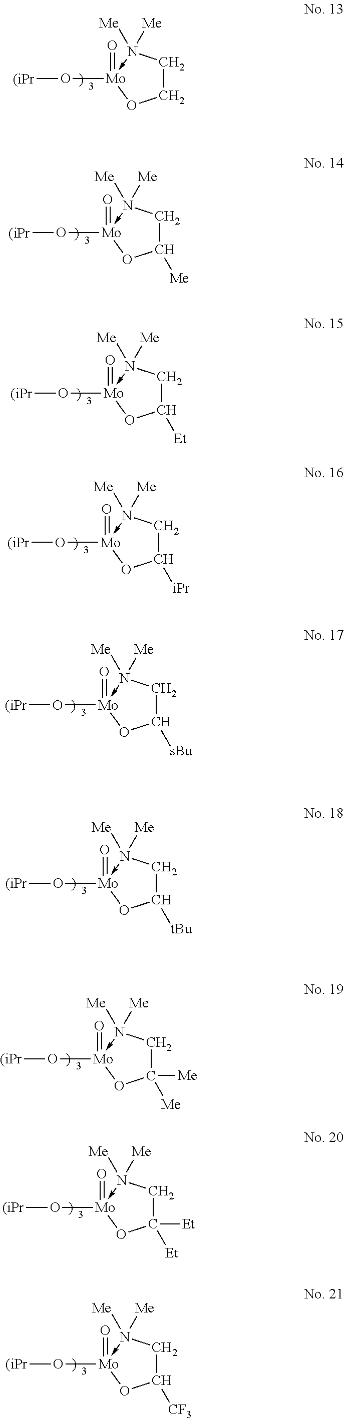

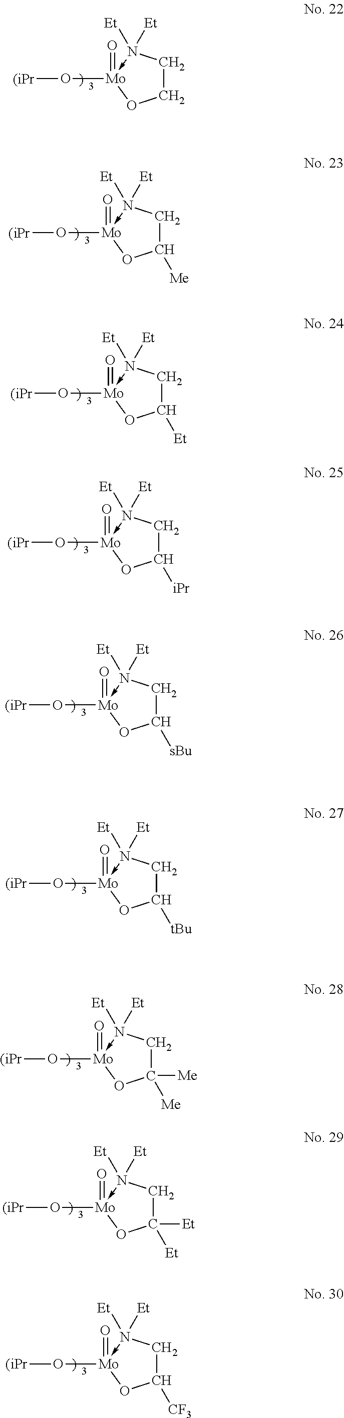

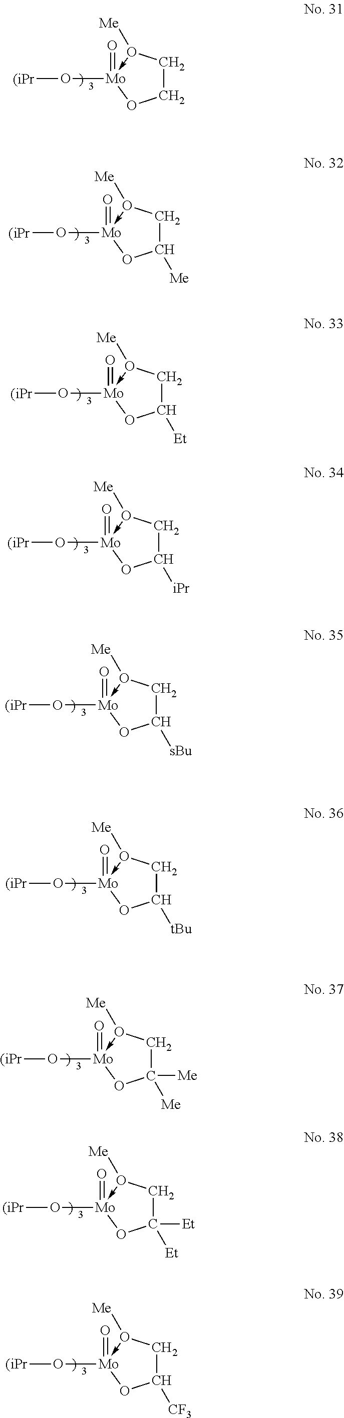

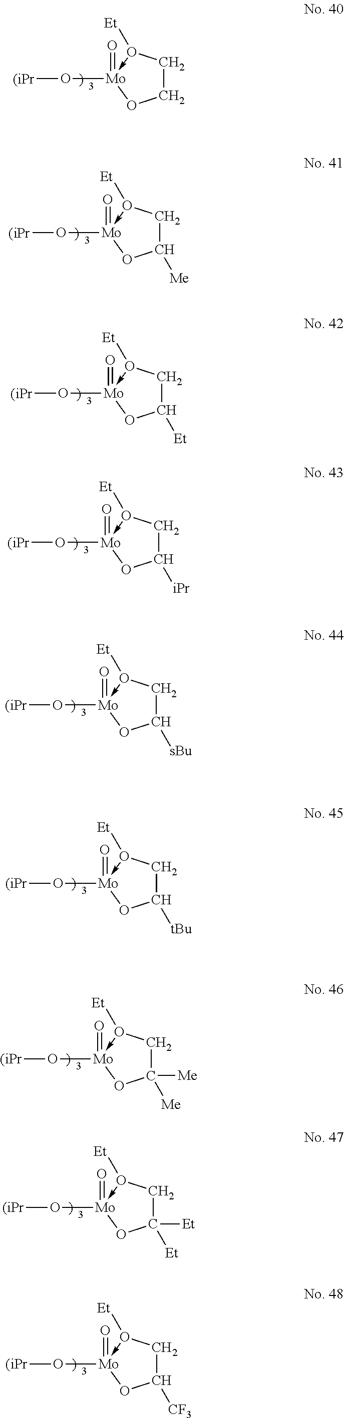

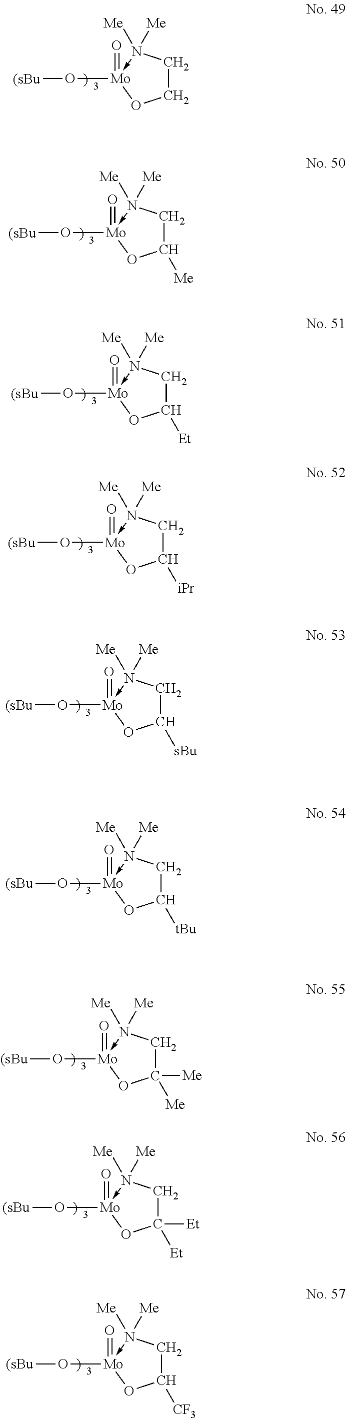

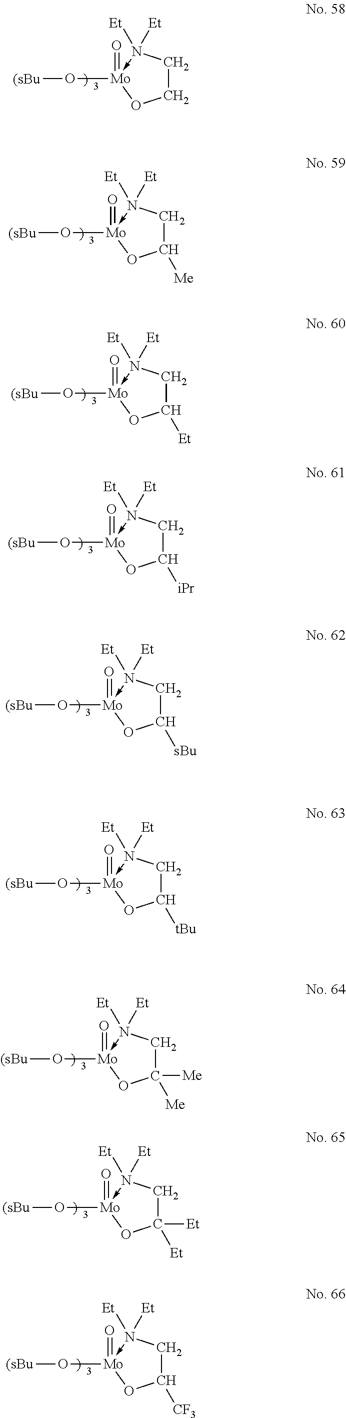

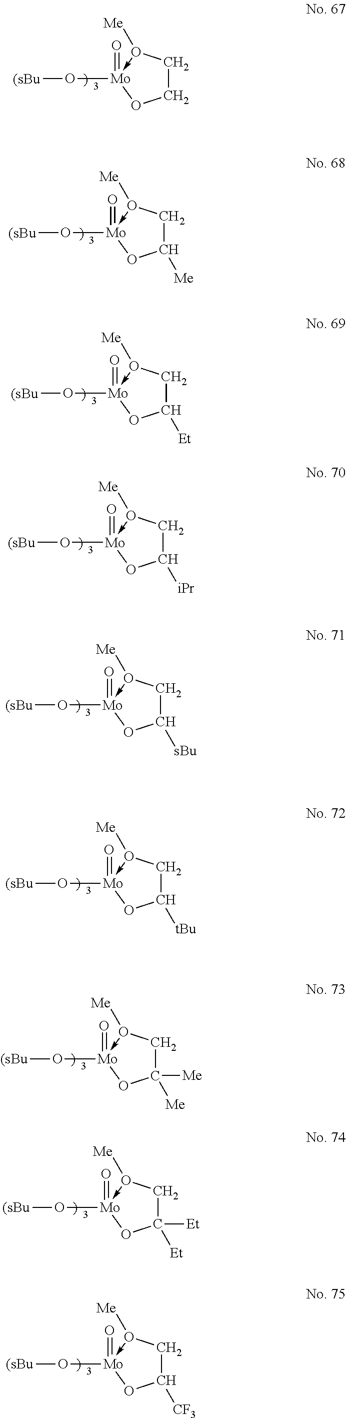

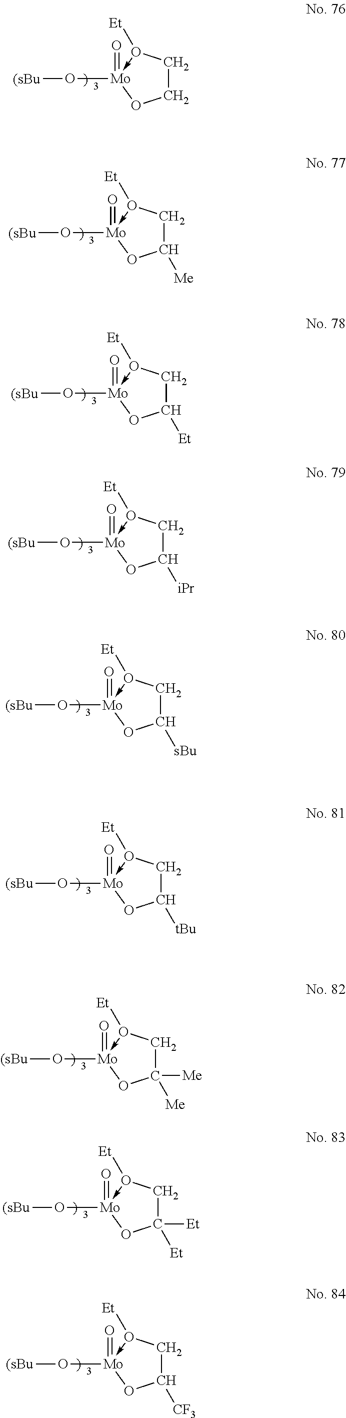

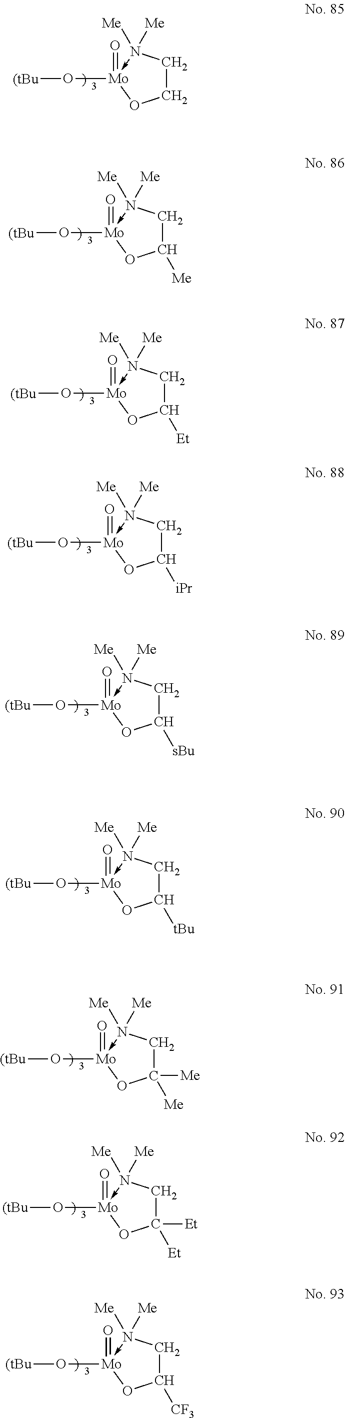

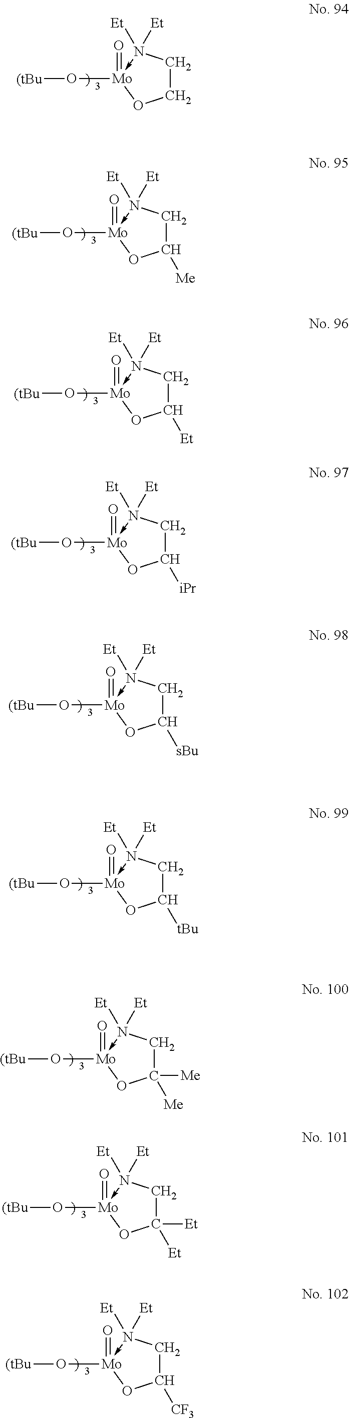

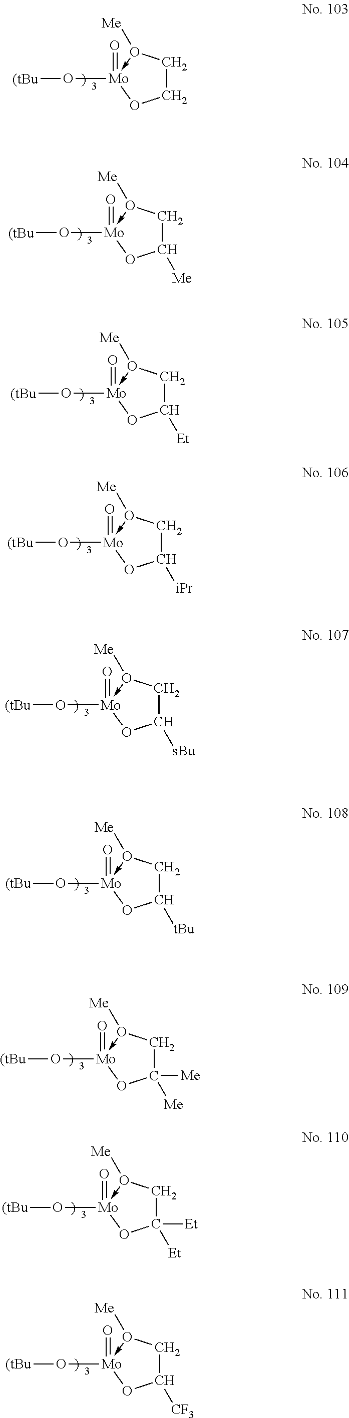

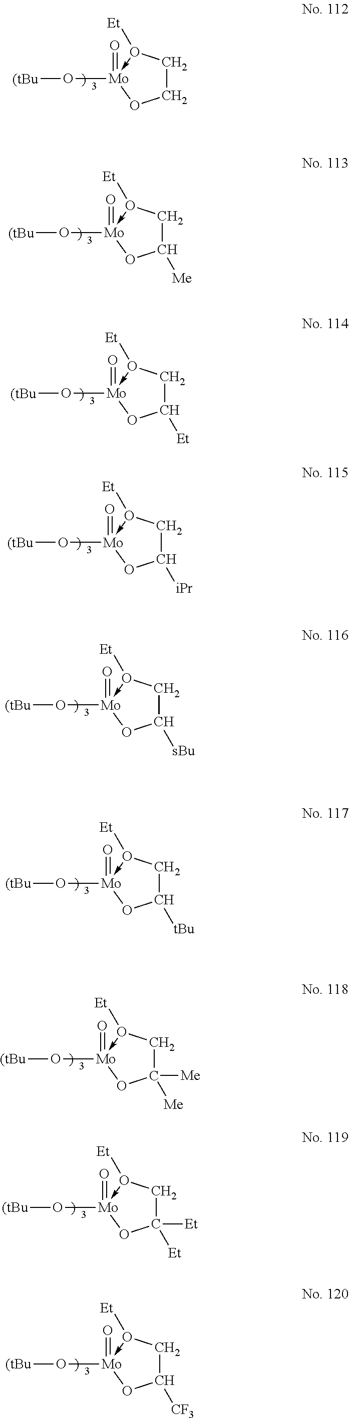

Of the above-mentioned compounds, Compounds Nos. 4, 10, 11, 12, 50, 85, 86, 90, 91, and 109 are preferred. From the viewpoints of the thermal stability of the compound and the productivity of a thin-film, Compounds Nos. 10, 11, 12, 86, 90, and 91 are more preferred, Compounds Nos. 10, 11, and 12 are still more preferred, and Compound No. 10 is most preferred.

A method of producing the molybdenum compound represented by the general formula (1) is not particularly limited, and the compound is produced by applying a well-known reaction. As a production method, in the case of a molybdenum compound in which “n” in the general formula (1) represents 4, the molybdenum compound represented by the general formula (1) may be obtained by, for example, causing molybdenum tetrachloride oxide, a fluorine atom-containing alcohol compound having a corresponding structure, and an alkyl lithium to react with each other in a diethyl ether solvent, followed by solvent exchange, filtration, solvent removal, and distillation purification.

Examples of the alcohol compound include 2-trifluoromethyl-2-propanol, 1,1,1,3,3,3-hexafluoro-2-methyl-2-propanol, nonafluoro-tert-butyl alcohol, and 1,1,1-trifluoroethanol.

As another production method, in the case of a molybdenum compound in which “n” in the general formula (1) represents 1 to 3, the molybdenum compound represented by the general formula (1) may be obtained by, for example, causing molybdenum tetrachloride oxide, an alcohol compound 1 having a corresponding structure, and an alkyl lithium to react with each other in a diethyl ether solvent, followed by solvent exchange, filtration, and solvent removal, and then causing the resultant to react with an alcohol compound 2 having a corresponding structure in a diethyl ether solvent, followed by solvent removal and distillation purification.

Examples of the alcohol compound 1 include isopropyl alcohol, sec-butyl alcohol, and tert-butyl alcohol.

Examples of the alcohol compound 2 include 2-dimethylaminoethanol, 1-dimethylamino-2-propanol, 1-dimethylamino-2-methyl-2-propanol, 1-dimethylamino-3,3-dimethylbutan-2-ol, and 1-methoxy-2-methyl-2-propanol.

The thin-film forming raw material of the present invention contains the molybdenum compound represented by the general formula (1) as a precursor of a thin-film. Its form varies depending on a production process to which the thin-film forming raw material is applied. For example, when a thin-film containing only a molybdenum atom as a metal is produced, the thin-film forming raw material of the present invention is free of a metal compound except the molybdenum compound represented by the general formula (1) and a semimetal compound. Meanwhile, when a thin-film containing two or more kinds of metals and/or a semimetal is produced, the thin-film forming raw material of the present invention may contain a compound containing a desired metal and/or a compound containing the semimetal (hereinafter sometimes referred to as “other precursor”) in addition to the molybdenum compound represented by the general formula (1). The thin-film forming raw material of the present invention may further contain an organic solvent and/or a nucleophilic reagent as described later. As described above, the physical properties of the molybdenum compound represented by the general formula (1) serving as the precursor are suitable for a CVD method, and hence the thin-film forming raw material of the present invention is useful as a chemical vapor deposition raw material (hereinafter sometimes referred to as “CVD raw material”). Of those, the molybdenum compound represented by the general formula (1) has an ALD window, and hence the thin-film forming raw material of the present invention is particularly suitable for an atomic layer deposition (hereinafter sometimes referred to as “ALD”) method. The thickness of the thin-film is preferably from 0.1 nm to 100 nm, more preferably from 0.3 nm to 30 nm. The thickness of the thin-film obtained per cycle by the atomic layer deposition method is preferably from 0.01 nm to 10 nm, more preferably from 0.03 nm to 3 nm.

When the thin-film forming raw material of the present invention is a chemical vapor deposition raw material, its form is appropriately selected in accordance with a procedure such as a transportation and supply method of the CVD method to be used.

As the above-mentioned transportation and supply method, there are given a gas transportation method and a liquid transportation method. The gas transportation method involves vaporizing the CVD raw material through heating and/or decompression in a vessel in which the CVD raw material is stored (hereinafter sometimes referred to as “raw material vessel”) to provide a raw material gas, and introducing the raw material gas into a film formation chamber (hereinafter sometimes referred to as “deposition reaction portion”) having a substrate set therein together with a carrier gas, such as argon, nitrogen, or helium, to be used as required. The liquid transportation method involves transporting the CVD raw material to a vaporization chamber under the state of a liquid or a solution, vaporizing the CVD raw material through heating and/or decompression in the vaporization chamber to provide a raw material gas, and introducing the raw material gas into the film formation chamber. In the case of the gas transportation method, the molybdenum compound represented by the general formula (1) itself may be used as the CVD raw material. In the case of the liquid transportation method, the compound represented by the general formula (1) itself or a solution obtained by dissolving the molybdenum compound in an organic solvent may be used as the CVD raw material. The CVD raw material may further contain the other precursor, a nucleophilic reagent, and the like.

In addition, in a multi-component CVD method, there are given a method involving vaporizing and supplying each component of the CVD raw material independently (hereinafter sometimes referred to as “single source method”), and a method involving vaporizing and supplying a mixed raw material obtained by mixing multiple components of the CVD raw material in desired composition in advance (hereinafter sometimes referred to as “cocktail source method”). In the case of the cocktail source method, a mixture of the molybdenum compound represented by the general formula (1) and the other precursor or a mixed solution obtained by dissolving the mixture in an organic solvent may be used as the CVD raw material. The mixture and the mixed solution may each further contain a nucleophilic reagent and the like.

There is no particular limitation on the above-mentioned organic solvent, and a well-known and general organic solvent may be used. Examples of the organic solvent include: acetic acid esters, such as ethyl acetate, butyl acetate, and methoxyethyl acetate; ethers, such as tetrahydrofuran, tetrahydropyran, ethylene glycol dimethyl ether, diethylene glycol dimethyl ether, triethylene glycol dimethyl ether, dibutyl ether, and dioxane; ketones, such as methyl butyl ketone, methyl isobutyl ketone, ethyl butyl ketone, dipropyl ketone, diisobutyl ketone, methyl amyl ketone, cyclohexanone, and methylcyclohexanone; hydrocarbons, such as hexane, cyclohexane, methylcyclohexane, dimethylcyclohexane, ethylcyclohexane, heptane, octane, toluene, and xylene; hydrocarbons each having a cyano group, such as 1-cyanopropane, 1-cyanobutane, 1-cyanohexane, cyanocyclohexane, cyanobenzene, 1,3-dicyanopropane, 1,4-dicyanobutane, 1,6-dicyanohexane, 1,4-dicyanocyclohexane, and 1,4-dicyanobenzene; and pyridine and lutidine. Those organic solvents may be used alone or as a mixture thereof in accordance with the solubility of a solute, a relationship among the use temperature, boiling point, and flash point of each of the solvents, and the like.

When the thin-film forming raw material of the present invention is a mixed solution with the above-mentioned organic solvent, the amount of the entire precursors in the thin-film forming raw material is preferably from 0.01 mol/liter to 2.0 mol/liter, more preferably from 0.05 mol/liter to 1.0 mol/liter because a thin-film can be produced with high productivity.

When the thin-film forming raw material of the present invention is free of a metal compound except the molybdenum compound represented by the general formula (1) and a semimetal compound, the term “amount of the entire precursors” as used herein means the amount of the molybdenum compound represented by the general formula (1). When the thin-film forming raw material of the present invention contains a compound containing any other metal and/or a compound containing a semimetal (other precursor) in addition to the molybdenum compound represented by the general formula (1), the term means the total amount of the molybdenum compound represented by the general formula (1) and the other precursor.

In addition, in the case of the multi-component CVD method, there is no particular limitation on the other precursor to be used together with the molybdenum compound represented by the general formula (1), and a well-known and general precursor used in the CVD raw material may be used.

Examples of the above-mentioned other precursor include compounds of: one kind or two or more kinds selected from the group consisting of compounds used as organic ligands, such as an alcohol compound, a glycol compound, a β-diketone compound, a cyclopentadiene compound, and an organic amine compound; and silicon or a metal. Examples of the kind of the metal in the other precursor include lithium, sodium, potassium, magnesium, calcium, strontium, barium, titanium, zirconium, hafnium, vanadium, tantalum, chromium, molybdenum, tungsten, manganese, iron, cobalt, rhodium, iridium, nickel, palladium, platinum, copper, silver, gold, zinc, aluminum, germanium, tin, lead, antimony, bismuth, yttrium, lanthanum, cerium, praseodymium, neodymium, promethium, samarium, europium, gadolinium, terbium, dysprosium, holmium, erbium, thulium, ytterbium, ruthenium, and lutetium.

Examples of the alcohol compound to be used as the organic ligand in the above-mentioned other precursor include: alkyl alcohols, such as methanol, ethanol, propanol, isopropyl alcohol, butanol, sec-butyl alcohol, isobutyl alcohol, tert-butyl alcohol, pentyl alcohol, isopentyl alcohol, and tert-pentyl alcohol; ether alcohols, such as 2-methoxyethanol, 2-ethoxyethanol, 2-butoxyethanol, 2-(2-methoxyethoxy) ethanol, 2-methoxy-1-methylethanol, 2-methoxy-1,1-dimethylethanol, 2-ethoxy-1,1-dimethylethanol, 2-isopropoxy-1,1-dimethylethanol, 2-butoxy-1,1-dimethylethanol, 2-(2-methoxyethoxy)-1,1-dimethylethanol, 2-propoxy-1,1-diethylethanol, 2-s-butoxy-1,1-diethylethanol, and 3-methoxy-1,1-dimethylpropanol; and dialkylamino alcohols, such as dimethylaminoethanol, ethylmethylaminoethanol, diethylaminoethanol, dimethylamino-2-pentanol, ethylmethylamino-2-pentanol, dimethylamino-2-methyl-2-pentanol, ethylmethylamino-2-methyl-2-pentanol, and diethylamino-2-methyl-2-pentanol.

Examples of the glycol compound to be used as the organic ligand in the above-mentioned other precursor include 1,2-ethanediol, 1,2-propanediol, 1,3-propanediol, 2,4-hexanediol, 2,2-dimethyl-1,3-propanediol, 2,2-diethyl-1,3-propanediol, 1,3-butanediol, 2,4-butanediol, 2,2-diethyl-1,3-butanediol, 2-ethyl-2-butyl-1,3-propanediol, 2,4-pentanediol, 2-methyl-1,3-propanediol, 2-methyl-2,4-pentanediol, 2,4-hexanediol, and 2,4-dimethyl-2,4-pentanediol.

Examples of the β-diketone compound to be used as the organic ligand in the above-mentioned other precursor include: alkyl-substituted β-diketones, such as acetylacetone, hexane-2,4-dione, 5-methylhexane-2,4-dione, heptane-2,4-dione, 2-methylheptane-3,5-dione, 5-methylheptane-2,4-dione, 6-methylheptane-2,4-dione, 2,2-dimethylheptane-3,5-dione, 2,6-dimethylheptane-3,5-dione, 2,2,6-trimethylheptane-3,5-dione, 2,2,6,6-tetramethylheptane-3,5-dione, octane-2,4-dione, 2,2,6-trimethyloctane-3,5-dione, 2,6-dimethyloctane-3,5-dione, 2,9-dimethylnonane-4,6-dione, 2-methyl-6-ethyldecane-3,5-dione, and 2,2-dimethyl-6-ethyldecane-3,5-dione; fluorine-substituted alkyl β-diketones, such as 1,1,1-trifluoropentane-2,4-dione, 1,1,1-trifluoro-5,5-dimethylhexane-2,4-dione, 1,1,1,5,5,5-hexafluoropentane-2,4-dione, and 1,3-diperfluorohexylpropane-1,3-dione; and ether-substituted β-diketones, such as 1,1,5,5-tetramethyl-1-methoxyhexane-2,4-dione, 2,2,6,6-tetramethyl-1-methoxyheptane-3,5-dione, and 2,2,6,6-tetramethyl-1-(2-methoxyethoxy) heptane-3,5-dione.

Examples of the cyclopentadiene compound to be used as the organic ligand in the above-mentioned other precursor include cyclopentadiene, methylcyclopentadiene, propylcyclopentadiene, ethylcyclopentadiene, isopropylcyclopentadiene, butylcyclopentadiene, sec-butylcyclopentadiene, isobutylcyclopentadiene, tert-butylcyclopentadiene, dimethylcyclopentadiene, and tetramethylcyclopentadiene.

Examples of the organic amine compound to be used as the organic ligand in the above-mentioned other precursor include methylamine, ethylamine, propylamine, isopropylamine, butylamine, sec-butylamine, tert-butylamine, isobutylamine, dimethylamine, diethylamine, dipropylamine, diisopropylamine, ethylmethylamine, propylmethylamine, and isopropylmethylamine.

The above-mentioned other precursors are known in the art, and production methods therefor are also known. An example of the production methods is given below. When the alcohol compound is used as the organic ligand, the precursor may be produced through a reaction between an inorganic salt of the metal described above or a hydrate thereof and an alkali metal alkoxide of the alcohol compound. In this case, examples of the inorganic salt of the metal or the hydrate thereof may include a halide and a nitrate of the metal, and examples of the alkali metal alkoxide may include a sodium alkoxide, a lithium alkoxide, and a potassium alkoxide.

In the case of the single source method, a compound similar to the molybdenum compound represented by the general formula (1) in the behavior of thermal decomposition and/or oxidative decomposition is preferably used as the above-mentioned other precursor. In the case of the cocktail source method, a compound that is not only similar to the molybdenum compound represented by the general formula (1) in the behavior of thermal decomposition and/or oxidative decomposition but also does not cause any change impairing desired characteristics as a precursor through a chemical reaction or the like at the time of mixing is preferably used as the above-mentioned other precursor because a high-quality thin-film can be produced with high productivity.

In addition, the thin-film forming raw material of the present invention may contain a nucleophilic reagent as required in order to impart the stability of each of the molybdenum compound represented by the general formula (1) and the other precursor. Examples of the nucleophilic reagent include: ethylene glycol ethers, such as glyme, diglyme, triglyme, and tetraglyme; crown ethers, such as 18-crown-6, dicyclohexyl-18-crown-6, 24-crown-8, dicyclohexyl-24-crown-8, and dibenzo-24-crown-8; polyamines, such as ethylenediamine, N,N′-tetramethylethylenediamine, diethylenetriamine, triethylenetetramine, tetraethylenepentamine, pentaethylenehexamine, 1,1,4,7,7-pentamethyldiethylenetriamine, 1,1,4,7,10,10-hexamethyltriethylenetetramine, and triethoxytriethyleneamine; cyclic polyamines, such as cyclam and cyclen; heterocyclic compounds, such as pyridine, pyrrolidine, piperidine, morpholine, N-methylpyrrolidine, N-methylpiperidine, N-methylmorpholine, tetrahydrofuran, tetrahydropyran, 1,4-dioxane, oxazole, thiazole, and oxathiolane; β-keto esters, such as methyl acetoacetate, ethyl acetoacetate, and 2-methoxyethyl acetoacetate; and β-diketones, such as acetylacetone, 2,4-hexanedione, 2,4-heptanedione, 3,5-heptanedione, and dipivaloylmethane. The usage amount of each of those nucleophilic reagents is preferably from 0.1 mol to 10 mol, more preferably from 1 mol to 4 mol with respect to 1 mol of the amount of the entire precursors because a high-quality thin-film can be produced with high productivity.

The thin-film forming raw material of the present invention is prevented from containing impurity metal elements except the components for forming the raw material, impurity halogens such as impurity chlorine, and impurity organic substances to the extent possible. The content of each of the impurity metal elements is preferably 100 ppb or less, more preferably 10 ppb or less, and the total content thereof is preferably 1 ppm or less, more preferably 100 ppb or less because a high-quality thin-film can be produced with high productivity. In particular, when the raw material is used for the gate insulating film, gate film, or barrier layer of an LSI, the contents of an alkali metal element and an alkaline-earth metal element that influence the electrical characteristics of a thin-film to be obtained need to be reduced. The content of the impurity halogens is preferably 100 ppm or less, more preferably 10 ppm or less, most preferably 1 ppm or less because a high-quality thin-film can be produced with high productivity. The total content of the impurity organic substances is preferably 500 ppm or less, more preferably 50 ppm or less, most preferably 10 ppm or less because a high-quality thin-film can be produced with high productivity. In addition, moisture causes generation of particles in the chemical vapor deposition raw material and generation of particles during thin-film formation. Accordingly, moisture in each of the precursor, the organic solvent, and the nucleophilic reagent is preferably removed as much as possible before its use. The moisture content of each of the precursor, the organic solvent, and the nucleophilic reagent is preferably 10 ppm or less, more preferably 1 ppm or less.

In addition, it is preferred that the thin-film forming raw material of the present invention be prevented from containing particles to the extent possible in order to reduce or prevent particle contamination of a thin-film to be formed. Specifically, in particle measurement with a light scattering liquid particle detector in a liquid phase, it is preferred that the number of particles larger than 0.3 μm be 100 or less in 1 mL of the liquid phase, it is more preferred that the number of particles larger than 0.2 μm be 1,000 or less in 1 mL of the liquid phase, and it is most preferred that the number of particles larger than 0.2 μm be 100 or less in 1 mL of the liquid phase.

Next, a method of producing a thin-film including using the thin-film forming raw material of the present invention is described. The method of producing a thin-film of the present invention is a production method comprising forming a thin-film containing a molybdenum atom on the surface of a substrate through use of the above-mentioned thin-film forming raw material of the present invention. More specifically, a method of producing a thin-film comprising forming a thin-film containing a molybdenum atom on the surface of a substrate through use of a raw material gas obtained by vaporizing the thin-film forming raw material of the present invention can be used. It is preferred that the production method of the present invention comprise: a raw material introduction step of introducing a raw material gas obtained by vaporizing the above-mentioned thin-film forming raw material into a film formation chamber having the substrate set therein; and a thin-film formation step of subjecting the molybdenum compound represented by the general formula (1) in the raw material gas to decomposition and/or a chemical reaction, to thereby form the thin-film containing a molybdenum atom on the surface of the substrate. Specifically, the method is preferably a CVD method including: introducing the raw material gas obtained by vaporizing the thin-film forming raw material of the present invention and a reactive gas to be used as required into the film formation chamber (treatment atmosphere) having the substrate set therein; and then subjecting a precursor in the raw material gas to decomposition and/or a chemical reaction on the substrate, y grow and deposit the thin-film containing a molybdenum atom on the surface of the substrate. A transportation and supply method for the raw material, a deposition method therefor, production conditions, a production apparatus, and the like are not particularly limited, and well-known and general conditions and methods may be used.

Examples of the above-mentioned reactive gas to be used as required include: oxidizing gases, such as oxygen, ozone, and water vapor; reducing gases, such as a hydrocarbon compound, for example, methane or ethane, hydrogen, carbon monoxide, and an organic metal compound; and nitriding gases, such as an organic amine compound, for example, a monoalkylamine, a dialkylamine, a trialkylamine, or an alkylenediamine, hydrazine, and ammonia. Those reactive gases may be used alone or as a mixture thereof. The molybdenum compound represented by the general formula (1) has such a property as to satisfactorily react with the reducing gas, and has such a property as to particularly satisfactorily react with hydrogen. Accordingly, the reducing gas is preferably used as the reactive gas, and hydrogen is particularly preferably used.

In addition, examples of the above-mentioned transportation and supply method include the gas transportation method, the liquid transportation method, the single source method, and the cocktail source method described above.

In addition, examples of the above-mentioned deposition method include: a thermal CVD method including causing a raw material gas or the raw material gas and a reactive gas to react only with heat, to thereby deposit a thin-film; a plasma CVD method using heat and plasma; a photo CVD method using heat and light; a photo-plasma CVD method using heat, light, and plasma; and an ALD method including dividing a deposition reaction of a CVD method into elementary steps, and performing deposition at a molecular level in a stepwise manner.

Examples of a material for the above-mentioned substrate include: silicon; ceramics, such as silicon nitride, titanium nitride, tantalum nitride, titanium oxide, ruthenium oxide, zirconium oxide, hafnium oxide, and lanthanum oxide; glass; and metals such as metal molybdenum. Examples of the shape of the substrate include a plate shape, a spherical shape, a fibrous shape, and a scaly shape. The surface of the substrate may be planar, or may have a three-dimensional structure such as a trench structure.

In addition, examples of the above-mentioned production conditions include a reaction temperature (substrate temperature), a reaction pressure, and a deposition rate. The reaction temperature is preferably from 25° C. to 700° C., more preferably from 100° C. to 400° C. because a high-quality thin-film can be produced with high productivity. In addition, the reaction pressure is preferably from 10 Pa to an atmospheric pressure in the case of the thermal CVD method or the photo CVD method, and is preferably from 10 Pa to 2,000 Pa in the case of using plasma because a high-quality thin-film can be produced with high productivity.

In addition, the deposition rate may be controlled by the supply conditions (vaporization temperature and vaporization pressure) of the raw material, the reaction temperature, and the reaction pressure. When the deposition rate is high, the characteristics of a thin-film to be obtained may deteriorate. When the deposition rate is low, a problem may occur in productivity. Accordingly, the deposition rate is preferably from 0.01 nm/min to 100 nm/min, more preferably from 0.1 nm/min to 50 nm/min. In addition, in the case of the ALD method, the deposition rate is controlled by the number of cycles so that a desired film thickness may be obtained.

Further, examples of the above-mentioned production conditions include a temperature and a pressure at the time of the vaporization of the thin-film forming raw material to provide the raw material gas. The step of vaporizing the thin-film forming raw material to provide the raw material gas may be performed in the raw material vessel or in the vaporization chamber. In any case, it is preferred that the thin-film forming raw material of the present invention be vaporized at from 0° C. to 150° C. In addition, when the thin-film forming raw material is vaporized in the raw material vessel or in the vaporization chamber to provide the raw material gas, the pressure in the raw material vessel and the pressure in the vaporization chamber are each preferably from 1 Pa to 10,000 Pa because a high-quality thin-film can be produced with high productivity.

The method of producing a thin-film of the present invention is preferably a method adopting the ALD method out of the CVD methods. In the case of the method adopting the ALD method, for example, it is preferred that: the production method comprise, between the above-mentioned raw material introduction step and thin-film formation step, a precursor thin-film formation step of forming a precursor thin-film on the surface of the substrate through use of the thin-film forming raw material; and the thin-film formation step be a step of causing the precursor thin-film to react with a reactive gas, to thereby form the thin-film containing a molybdenum atom on the surface of the substrate. Further, the method is more preferably a method of producing a thin-film comprising an evacuation step of evacuating an unreacted compound gas. The precursor thin-film formation step may comprise a step of depositing the thin-film forming raw material on the surface of the substrate.

The respective steps of the above-mentioned ALD method are described in detail below by taking a case in which a metal molybdenum film is formed as a kind of thin-film containing a molybdenum atom as an example. First, the above-mentioned raw material introduction step is performed. A preferred temperature and a preferred pressure when the thin-film forming raw material is turned into the raw material gas are the same as those described in the method of producing a thin-film by the CVD method. Next, when the raw material gas introduced into the film formation chamber and the surface of the substrate are brought into contact with each other, a precursor thin-film is formed on the surface of the substrate (precursor thin-film formation step).

In the above-mentioned precursor thin-film formation step, heat may be applied by heating the substrate or by heating the film formation chamber. The temperature of the substrate in this case is preferably from 25° C. to 700° C., more preferably from 100° C. to 400° C. The pressure of a system (the inside of the film formation chamber) when this step is performed is preferably from 1 Pa to 10,000 Pa, more preferably from 10 Pa to 1,000 Pa. When the thin-film forming raw material contains the other precursor except the molybdenum compound of the present invention, the other precursor is also deposited on the surface of the substrate together with the molybdenum compound of the present invention.

Next, a gas of the thin-film forming raw material that has not been deposited on the surface of the substrate is evacuated from the film formation chamber (evacuation step). Although it is ideal that a gas of the thin-film forming raw material that is unreacted and a by-product gas be completely evacuated from the film formation chamber, it is not always required that the gases be completely evacuated. A method for the evacuation is, for example, a method including purging the inside of the system with an inert gas, such as nitrogen, helium, or argon, a method including decompressing the inside of the system to evacuate the gas, or a combination of these methods. The degree of decompression when the decompression is performed is preferably from 0.01 Pa to 300 Pa, more preferably from 0.01 Pa to 100 Pa because a high-quality thin-film can be produced with high productivity.

Next, a reducing gas serving as the reactive gas is introduced into the film formation chamber, and the metal molybdenum film is formed from the precursor thin-film obtained in the previous precursor thin-film formation step through the action of the reducing gas or the action of the reducing gas and heat (molybdenum-containing thin-film formation step). A temperature when the heat is applied in this step is preferably from 25° C. to 700° C., more preferably from 100° C. to 400° C. because a high-quality thin-film can be produced with high productivity. The pressure of the system (inside of the film formation chamber) when this step is performed is preferably from 1 Pa to 10,000 Pa, more preferably from 10 Pa to 1,000 Pa because a high-quality thin-film can be produced with high productivity. The molybdenum compound represented by the general formula (1) has satisfactory reactivity with the reducing gas, and hence a high-quality metal molybdenum film having a low residual carbon content can be obtained.

In the case where the ALD method is adopted in the method of producing a thin-film of the present invention as described above, the following may be performed: thin-film deposition by a series of operations consisting of the raw material introduction step, the precursor thin-film formation step, the evacuation step, and the molybdenum-containing thin-film formation step described above is defined as one cycle; and the cycle is repeated a plurality of times until a thin-film having a required thickness is obtained. In this case, the following is preferably performed: after the performance of one cycle, the compound gas and the reactive gas that are unreacted, and the by-product gas are evacuated from a deposition reaction portion in the same manner as in the above-mentioned evacuation step, and then the next one cycle is performed.

In addition, in the formation of the metal molybdenum film by the ALD method, energy, such as plasma, light, or a voltage, may be applied, and a catalyst may be used. There are no particular limitations on the timing of the application of the energy and the timing of the use of the catalyst. The energy may be applied or the catalyst may be used, for example, at the time of the introduction of the compound gas in the raw material introduction step, at the time of heating in the precursor thin-film formation step or the molybdenum-containing thin-film formation step, at the time of the evacuation of the inside of the system in the evacuation step, or at the time of the introduction of the reducing gas in the molybdenum-containing thin-film formation step, or between the above-mentioned respective steps.

In addition, in the method of producing a thin-film of the present invention, after the thin-film deposition, annealing treatment may be performed under an inert atmosphere, an oxidizing atmosphere, or a reducing atmosphere for obtaining more satisfactory electrical characteristics. In the case where step embedding is required, a reflow step may be provided. The temperature in the chamber in this case is preferably from 200° C. to 1,000° C., more preferably from 250° C. to 500° C.

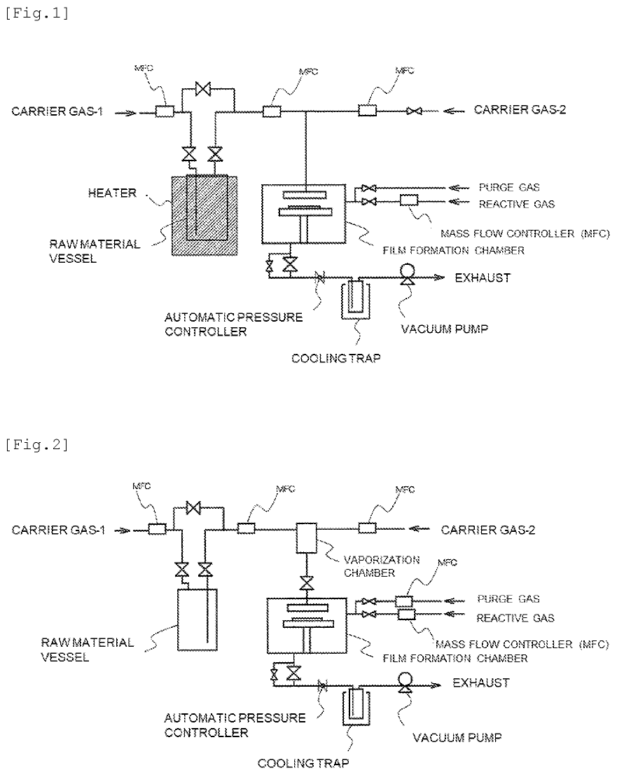

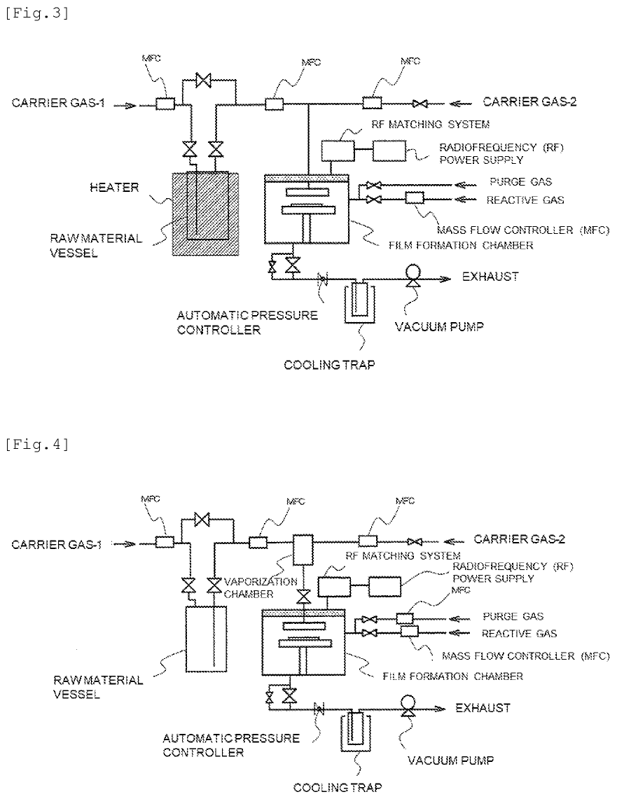

A well-known ALD apparatus may be used in the method of producing a thin-film of the present invention. Specific examples of the ALD apparatus include such an apparatus capable of performing bubbling supply of a precursor as illustrated in each of FIG. 1 and FIG. 3, and such an apparatus including a vaporization chamber as illustrated in each of FIG. 2 and FIG. 4. Another example thereof is such an apparatus capable of subjecting the reactive gas to plasma treatment as illustrated in each of FIG. 3 and FIG. 4. The apparatus is not limited to such single-substrate type apparatus each including a film formation chamber r (hereinafter referred to as “deposition reaction portion”) as illustrated in FIG. 1 to FIG. 4, and an apparatus capable of simultaneously processing a large number of substrates through use of a batch furnace may be used. Those apparatus may also be used as CVD apparatus.

A thin-film produced by using the thin-film forming raw material of the present invention may be formed as desired kinds of thin-films, such as thin-films of a metal, oxide ceramics, nitride ceramics, and glass, by appropriately selecting the other precursor, the reactive gas, and the production conditions. It has been known that the thin-film exhibits electrical characteristics, optical characteristics, and the like. Thus, the thin-film has been applied to various applications. Examples thereof include a metal thin-film, a metal oxide thin-film, a metal nitride thin-film, an alloy thin-film, and a metal-containing composite oxide thin-film. Those thin-films have been widely used in the production of, for example, an electrode material for a memory element typified by a DRAM element, a wiring material, a resistance film, a diamagnetic film used for the recording layer of a hard disk, and a catalyst material for a polymer electrolyte fuel cell.

A compound of the present invention is a molybdenum compound represented by the general formula (2). The compound of the present invention has a low melting point and a high vapor pressure, is excellent in thermal stability, and can be applied to an ALD method, and is hence a compound suitable as a precursor in a method of producing a thin-film comprising a vaporization step, such as an ALD method.

In the general formula (2), R²¹ represents an alkyl group having 1 to 5 carbon atoms or a fluorine atom-containing alkyl group having 1 to 5 carbon atoms, L² represents a group represented by the general formula (L-3) or (L-4), and “m” represents an integer of from 1 to 4, provided that when “m” represents 4, R²¹ represents a fluorine atom-containing alkyl group having 1 to 5 carbon atoms and having 1 to 8 fluorine atoms.

Examples of the alkyl group having 1 to 5 carbon atoms represented by R²¹ include the same alkyl groups as those listed as the alkyl group having 1 to 5 carbon atoms represented by R¹ in the general formula (1).

Examples of the fluorine atom-containing alkyl group having 1 to 5 carbon atoms represented by R²¹ include the same alkyl groups as those listed as the fluorine atom-containing alkyl group having 1 to 5 carbon atoms represented by R¹ in the general formula (1).

Examples of the fluorine atom-containing alkyl group having 1 to 5 carbon atoms and having 1 to 8 fluorine atoms represented by R²¹ include a monofluoromethyl group, a difluoromethyl group, a trifluoromethyl group, a trifluoroethyl group, a trifluoropropyl group, a dimethyltrifluoroethyl group, a (trifluoromethyl)tetrafluoroethyl group, a hexafluoro-tert-butyl group, and a di-(trifluoromethyl)ethyl group.

In the general formulae (L-3) and (L-4), R²² to R³² each independently represent a hydrogen atom, an alkyl group having 1 to 5 carbon atoms, or a fluorine atom-containing alkyl group having 1 to 5 carbon atoms, and * represents a bonding site.

Examples of the alkyl group having 1 to 5 carbon atoms represented by each of R²² to R³² include the same alkyl groups as those listed as the alkyl group having 1 to 5 carbon atoms represented by each of R² to R¹² in the general formula (1).

Examples of the fluorine atom-containing alkyl group having 1 to 5 carbon atoms represented by each of R²² to R³² include the same alkyl groups as those listed as the fluorine atom-containing 1 group having 1 to 5 carbon atoms represented by each of R² to R¹² in the general formula (1).

In the general formulae (2), (L-3), and (L-4), R²¹ to R³², L², and “m” are appropriately selected in accordance with a method of producing a thin-film to be applied. When the compound of the present invention is used in a method of producing a thin-film comprising a step of vaporizing a compound,

R²¹ to R³², L², and “m” are preferably selected so that the compound may have at least one property selected from a high vapor pressure, a low melting point, and high thermal stability, and R²¹ to R³², L², and “m” are more preferably selected so that the compound may have high thermal stability.

R²¹ preferably represents an alkyl group having 2 to 4 carbon atoms or a fluorine atom-containing alkyl group having 2 to 4 carbon atoms because the compound has high thermal stability, and can produce a high-quality thin-film with high productivity when used as a thin-film forming raw material. More specifically, when “m” represents 1 to 3, R²¹ represents preferably an alkyl group having 3 or 4 carbon atoms, more preferably a sec-butyl group or a tert-butyl group, particularly preferably a tert-butyl group, and when “m” represents 4, R²¹ represents preferably a fluorine atom-containing alkyl group having 3 or 4 carbon atoms, more preferably a fluorine atom-containing alkyl group having 4 carbon atoms, particularly preferably a dimethyl trifluoroethyl group. When R²¹ represents a fluorine atom-containing alkyl group, R²¹ has preferably 1 to 12 fluorine atoms, more preferably 1 to 8 fluorine atoms, particularly preferably 1 to 4 fluorine atoms, most preferably 3 fluorine atoms because the compound has high thermal stability, and can produce a high-quality thin-film with high productivity when used as a thin-film forming raw material. L² preferably represents a group represented by the general formula (L-3) because the compound has a low melting point and high thermal stability, and can produce a high-quality thin-film with high productivity when used as a thin-film forming raw material. “m” represents preferably 3 or 4, more preferably 4 because the compound has high thermal stability, and can produce a high-quality thin-film with high productivity when used as a thin-film forming raw material.

R²² represents preferably a hydrogen atom or an alkyl group having 1 to 5 carbon atoms, more preferably an alkyl group having 1 to 5 carbon atoms, still more preferably an alkyl group having 1 to 3 carbon atoms, particularly preferably a methyl group because the compound has a high vapor pressure, and can produce a high-quality thin-film with high productivity when used as a thin-film forming raw material. R²³ represents preferably a hydrogen atom or an alkyl group having 1 to 5 carbon atoms, more preferably a hydrogen atom or an alkyl group having 1 to 3 carbon atoms, still more preferably a hydrogen atom or a methyl group, particularly preferably a hydrogen atom because the compound has a high vapor pressure, and can produce a high-quality thin-film with high productivity when used as a thin-film forming raw material. R²⁴ and R²⁵ each independently represent preferably a hydrogen atom or an alkyl group having 1 to 5 carbon atoms, more preferably a hydrogen atom or an alkyl group having 1 to 3 carbon atoms, particularly preferably a hydrogen atom because the compound has a high vapor pressure, and can produce a high-quality thin-film with high productivity when used as a thin-film forming raw material. R²⁶ and R²⁷ each independently represent preferably a hydrogen atom or an alkyl group having 1 to 5 carbon atoms, more preferably an alkyl group having 1 to 5 carbon atoms, still more preferably an alkyl group having 1 to 3 carbon atoms, particularly preferably a methyl group because the compound has a high vapor pressure and high thermal stability, and can produce a high-quality thin-film with high productivity when used as a thin-film forming raw material.

R²⁸ represents preferably a hydrogen atom or an alkyl group having 1 to 5 carbon atoms, more preferably an alkyl group having 1 to 5 carbon atoms, still more preferably an alkyl group having 1 to 3 carbon atoms, particularly preferably a methyl group because the compound has a high vapor pressure, and can produce a high-quality thin-film with high productivity when used as a thin-film forming raw material. R²⁹ represents preferably a hydrogen atom or an alkyl group having 1 to 5 carbon atoms, more preferably a hydrogen atom or an alkyl group having 1 to 3 carbon atoms, still more preferably a hydrogen atom or a methyl group, particularly preferably a methyl group because the compound has a high vapor pressure, and can produce a high-quality thin-film with high productivity when used as a thin-film forming raw material. R³⁰ and R³¹ each independently represent preferably a hydrogen atom or an alkyl group having 1 to 5 carbon atoms, more preferably a hydrogen atom or an alkyl group having 1 to 3 carbon atoms, particularly preferably a hydrogen atom because the compound has a high vapor pressure, and can produce a high-quality thin-film with high productivity when used as a thin-film forming raw material. R³² represents preferably a hydrogen atom or an alkyl group having 1 to 5 carbon atoms, more preferably an alkyl group having 1 to 5 carbon atoms, still more preferably an alkyl group having 1 to 3 carbon atoms, particularly preferably a methyl group because the compound has a high vapor pressure and high thermal stability, and can produce a high-quality thin-film with high productivity when used as a thin-film forming raw material.

In addition, when the compound of the present invention is used in a method of producing a thin-film by a MOD method free of any vaporization step, R²¹ to R³², L², and “m” may be arbitrarily selected in accordance with, for example, the solubility of the compound in a solvent to be used and a thin- film formation reaction.

Specific examples of the molybdenum compound represented by the general formula (2) include Compounds No. 1to No. 11 and No. 13 to No. 120 described above.

The molybdenum compound represented by the general formula (2) may be produced by the same method as in the case of the molybdenum compound represented by the general formula (1).

### EXAMPLES

The present invention is described in more detail below by way of the Examples, the Comparative Examples, and the Evaluation Examples. However, the present invention is by no means limited by Examples and the like below. In the following Examples, “%” is by mass unless otherwise stated.

### Production of Compound of the Present Invention

The results of the production of the molybdenum compounds of the present invention are shown in Examples 1 to 10 below.

### [Example 1] Production of Compound No. 4

1.00 Gram (0.0039 mol) of molybdenum tetrachloride oxide and 12 ml of diethyl ether were loaded into a 100-milliliter three-necked flask under an Ar atmosphere, and were stirred at room temperature. A solution prepared from 1.58 g (0.0158 mol) of 1,1,1-trifluoroethanol, 15 ml of diethyl ether, and 10 ml (0.0158 mol) of a n-butyl lithium-hexane solution was dropped thereinto under ice cooling. After the dropping, the temperature of the mixture was returned to room temperature, stirring was performed for 14 hours, and the solvent was exchanged with hexane, followed by filtration. The solvent was removed from the resultant filtrate, and the residue was distilled at a bath temperature of 110° C. and a pressure of 50 Pa. Thus, Compound No. 4 was obtained as a yellow solid. The yield was 0.11 g, and the percent yield was 5.5%.

### Analysis Values

### (1) Normal-Pressure TG-DTA

50% mass loss temperature: 151° C. (Ar flow rate: 100 ml/min., temperature increase at 10° C./min., sample amount: 10.443 mg)

### (2) Reduced-Pressure TG-DTA

50% mass loss temperature: 95° C. (10 Torr, Ar flow rate: 50 ml/min., temperature increase at 10° C./min., sample amount: 9.654 mg)

### (3) ¹H-NMR (Deuterated Benzene)

4.403 ppm (8H, singlet)

### (4) Elemental Analysis (Metal Analysis: ICP-AES)

Mo content: 18.5 mass % (theoretical value: 18.9 mass %)

### [Example 2] Production of Compound No. 10

0.82 Gram (0.00322 mol) of molybdenum tetrachloride oxide and 15 ml of diethyl ether were loaded into a 100-milliliter three-necked flask under an Ar atmosphere, and were stirred at room temperature. A solution prepared from 1.65 g (0.0129 mol) of 2-trifluoromethyl-2-propanol, 10 ml of diethyl ether, and 8.2 ml (0.0129 mol) of a n-butyl lithium-hexane solution was dropped thereinto under ice cooling. After the dropping, the temperature of the mixture was returned to room temperature, stirring was performed for 18 hours, and the solvent was exchanged with hexane, followed by filtration. The solvent was removed from the resultant filtrate, and the residue was distilled at a bath temperature of 105° C. and a pressure of 74 Pa. Thus, Compound No. 10 was obtained as a yellowish brown solid. The yield was 0.29 g, and the percent yield was 15%.

### Analysis Values

### (1) Normal-Pressure TG-DTA

50% mass loss temperature: 179° C. (Ar flow rate: 100 ml/min., temperature increase at 10° C./min., sample amount: 9.773 mg)

### (2) Reduced-Pressure TG-DTA

50% mass loss temperature: 107° C. (10 Torr, Ar flow rate: 50 ml/min., temperature increase at 10° C./min., sample amount: 10.041 mg)

### (3) ¹H-NMR (Deuterated Benzene)

1.39 ppm (24H, singlet)

### (4) ¹⁹F-NMR (Deuterated Benzene)

−81.343 ppm

### (5) Elemental Analysis (Metal Analysis: ICP-AES)

Mo content: 15.5 mass % (theoretical value: 15.5 mass %)

### [Example 3] Production of Compound No. 11

0.61 Gram (0.0024 mol) of molybdenum tetrachloride oxide and 10 ml of diethyl ether were loaded into a 100-milliliter three-necked flask under an Ar atmosphere, and were stirred at room temperature. A solution prepared from 1.74 g (0.0096 mol) of 1,1,1,3,3,3-hexafluoro-2-methyl-2-propanol, 10 ml of diethyl ether, and 6.1 ml (0.0096 mol) of a n-butyl lithium-hexane solution was dropped thereinto under ice cooling. After the dropping, the temperature of the mixture was returned to room temperature, stirring was performed for 18 hours, and the solvent was exchanged with hexane, followed by filtration. The solvent was removed from the resultant filtrate, and the residue was distilled at a bath temperature of 100° C. and a pressure of 150 Pa. Thus, Compound No. 11 was obtained as a yellowish brown solid. The yield was 0.25 g, and the percent yield was 13%.

### Analysis Values

### (1) Normal-Pressure TG-DTA

50% mass loss temperature: 152° C. (Ar flow rate: 100 ml/min., temperature increase at 10° C./min., sample amount: 10.415 mg)

### (2) Reduced-Pressure TG-DTA

50% mass loss temperature: 95° C. (10 Torr, Ar flow rate: 50 ml/min., temperature increase at 10° C./min., sample amount: 9.984 mg)

### (3) ¹H-NMR (Deuterated Benzene)

1.45 ppm (12H, singlet)

### (4) ¹⁹F-NMR (Deuterated Benzene)

−75.904 ppm

### (5) Elemental Analysis (Metal Analysis: ICP-AES)

Mo content: 11.4 mass % (theoretical value: 11.5 mass %)

### [Example 4] Production of Compound No. 12

0.48 Gram (0.0019 mol) of molybdenum tetrachloride oxide and 10 ml of diethyl ether were loaded into a 100-milliliter three-necked flask under an Ar atmosphere, and were stirred at room temperature. A solution prepared from 1.79 g (0.0076 mol) of nonafluoro-tert-butyl alcohol, 10 ml of diethyl ether, and 4.8 ml (0.0076 mol) of a n-butyl lithium-hexane solution was dropped thereinto under ice cooling. After the dropping, the temperature of the mixture was returned to room temperature, stirring was performed for 18 hours, and the solvent was exchanged with hexane, followed by filtration. The solvent was removed from the resultant filtrate, and the residue was distilled at a bath temperature of 115° C. and a pressure of 55 Pa. Thus, Compound No. 12 was obtained as a yellow green solid. The yield was 0.10 g, and the percent yield was 5%.

### Analysis Values

### (1) Normal-Pressure TG-DTA

50% mass loss temperature: 176° C. (Ar flow rate: 100 ml/min., temperature increase at 10° C./min., sample amount: 10.321 mg)

### (2) Reduced-Pressure TG-DTA

50% mass loss temperature: 108° C. (10 Torr, Ar flow rate: 50 ml/min., temperature increase at 10° C./min., sample amount: 9.502 mg)

### (3) ¹⁹F-NMR (Deuterated Benzene)

−74.268 ppm

### (4) Elemental Analysis (Metal Analysis: ICP-AES)

Mo content: 9.2 mass % (theoretical value: 9.1 mass %)

### [Example 5] Production of Compound No. 50

1.17 Grams (0.0046 mol) of molybdenum tetrachloride oxide and 19 ml of diethyl ether were loaded into a 100-milliliter three-necked flask under an Ar atmosphere, and were stirred at room temperature. A solution prepared from 1.37 g (0.018 mol) of sec-butyl alcohol, 14 ml of diethyl ether, and 11.7 ml (0.018 mol) of a n-butyl lithium-hexane solution was dropped thereinto under ice cooling. After the dropping, the temperature of the mixture was returned to room temperature, stirring was performed for 18 hours, and the solvent was exchanged with hexane, followed by filtration. The solvent was removed from the resultant filtrate, and 10 ml of diethyl ether was added. Next, 0.48 g (0.0046 mol) of 1-dimethylamino-2-propanol was dropped thereinto at room temperature, and stirring was performed for 18 hours. After that, the solvent was removed, and the residue was distilled at a bath temperature of 128° C. and a pressure of 36 Pa. Thus, Compound No. 50 was obtained as a reddish brown liquid. The yield was 0.21 g, and the percent yield was 10.5%.

### Analysis Values

### (1) Normal-Pressure TG-DTA

50% mass loss temperature: 208° C. (Ar flow rate: 100 ml/min., temperature increase at 10° C./min., sample amount: 10.157 mg)

### (2) Reduced-Pressure TG-DTA

50% mass loss temperature: 145° C. (10 Torr, Ar flow rate: 50 ml/min., temperature increase at 10° C./min., sample amount: 9.980 mg)

### (3) ¹H-NMR (Deuterated Benzene)

0.953-1.060 ppm (9H, broad), 1.312-2. 009 ppm (18H, broad), 2.171-2.390 ppm (8H, broad), 4.082-4.855 ppm (4H, broad)

### (4) Elemental Analysis (Metal Analysis: ICP-AES)

Mo content: 22.0 mass % (theoretical value: 22.14 mass %)

### [Example 6] Production of Compound No. 85

1.21 Grams (0.0048 mol) of molybdenum tetrachloride oxide and 15 ml of diethyl ether were loaded into a 100-milliliter three-necked flask under an Ar atmosphere, and were stirred at room temperature. A solution prepared from 1.41 g (0.0191 mol) of tert-butyl alcohol, 20 ml of diethyl ether, and 12.2 ml (0.0191 mol) of a n-butyl lithium-hexane solution was dropped thereinto under ice cooling. After the dropping, the temperature of the mixture was returned to room temperature, stirring was performed for 18 hours, and the solvent was exchanged with hexane, followed by filtration. The solvent was removed from the resultant filtrate, and 20 ml of diethyl ether was added. Next, 0.43 g (0.0048 mol) of 2-dimethylaminoethanol was dropped thereinto at room temperature, and stirring was performed for 17 hours. After that, the solvent was removed, and the residue was distilled at a bath temperature of 155° C. and a pressure of 70 Pa. Thus, Compound No. 85 was obtained as a black liquid. The yield was 0.07 g, and the percent yield was 3.5%.

### Analysis Values

### (1) Normal-Pressure TG-DTA

50% mass loss temperature: 225° C. (Ar flow rate: 100 ml/min., temperature increase at 10° C./min., sample amount: 9.596 mg)

### (2) Reduced-Pressure TG-DTA

50% mass loss temperature: 149° C. (10 Torr, Ar flow rate: 50 ml/min., temperature increase at 10° C./min., sample amount: 9.624 mg)

### (3) ¹H-NMR (Deuterated Benzene)

1.482 ppm (27H, singlet), 1.819-1.848 ppm (2H, triplet), 2.249 ppm (6H, singlet), 3.898-3.927 ppm (2H, triplet)

### (4) Elemental Analysis (Metal Analysis: ICP-AES)

Mo content: 22.5 mass % (theoretical value: 22.9 mass %)

### [Example 7] Production of Compound No. 86

2.93 Grams (0.0115 mol) of molybdenum tetrachloride oxide and 48 ml of diethyl ether were loaded into a 100-milliliter three-necked flask under an Ar atmosphere, and were stirred at room temperature. A solution prepared from 3.43 g (0.0460 mol) of tert-butyl alcohol, 35 ml of diethyl ether, and 29.3 ml (0.0460 mol) of a n-butyl lithium-hexane solution was dropped thereinto under ice cooling. After the dropping, the temperature of the mixture was returned to room temperature, stirring was performed for 18 hours, and the solvent was exchanged with hexane, followed by filtration. The solvent was removed from the resultant filtrate, and 80 ml of diethyl ether was added. Next, 1.20 g (0.0115 mol) of 1-dimethylamino-2-propanol was dropped thereinto at room temperature, and stirring was performed for 17 hours. After that, the solvent was removed, and the residue was distilled at a bath temperature of 120° C., a pressure of 63 Pa, and a column top temperature of 108° C. Thus, Compound No. 86 was obtained as a brown solid. The yield was 0.96 g, and the percent yield was 19%.

### Analysis Values

### (1) Normal-Pressure TG-DTA

50% mass loss temperature: 198° C. (Ar flow rate: 100 ml/min., temperature increase at 10° C./min., sample amount: 10.351 mg)

### (2) Reduced-Pressure TG-DTA

50% mass loss temperature: 129° C. (10 Torr, Ar flow rate: 50 ml/min., temperature increase at 10° C./min., sample amount: 9.531 mg)

### (3) ¹H-NMR (Deuterated Benzene)

1.09-1.10 ppm (3H, doublet), 1.49 ppm (27H, singlet), 1.93-1.97 ppm (1H, double doublet), 2.29 ppm (3H, singlet), 2.35 ppm (3H, singlet), 2.42-2.47 ppm (1H, triplet), 4.41-4.50 ppm (1H, multiplet)

### (4) Elemental Analysis (Metal Analysis: ICP-AES)

Mo content: 22.2 mass % (theoretical value: 22.1 mass %)

### [Example 8] Production of Compound No. 90

1.17 Grams (0.0046 mol) of molybdenum tetrachloride oxide and 20 ml of diethyl ether were loaded into a 100-milliliter three-necked flask under an Ar atmosphere, and were stirred at room temperature. A solution prepared from 1.37 g (0.0184 mol) of tert-butyl alcohol, 15 ml of diethyl ether, and 11.7 ml (0.0184 mol) of a n-butyl lithium-hexane solution was dropped thereinto under ice cooling. After the dropping, the temperature of the mixture was returned to room temperature, stirring was performed for 18 hours, and the solvent was exchanged with hexane, followed by filtration. The solvent was removed from the resultant filtrate, and 20 ml of diethyl ether was added. Next, 0.67 g (0.0046 mol) of 1-dimethylamino-3,3-dimethylbutan-2-ol was dropped thereinto at room temperature, and stirring was performed for 17 hours. After that, the solvent was removed, and the residue was distilled at a bath temperature of 150° C. and a pressure of 180 Pa. Thus, Compound No. 90 was obtained as a red viscous liquid. The yield was 0.17 g, and the percent yield was 8.0%.

### Analysis Values

### (1) Normal-Pressure TG-DTA

50% mass loss temperature: 226° C. (Ar flow rate: 100 ml/min., temperature increase at 10° C./min., sample amount: 9.931 mg)

### (2) Reduced-Pressure TG-DTA

50% mass loss temperature: 151° C. (10 Torr, Ar flow rate: 50 ml/min., temperature increase at 10° C./min., sample amount: 9.890 mg)

### (3) ¹H-NMR (Deuterated Benzene)

0.71 ppm (9H, singlet), 1.43-1.52 ppm (27H, multiplet), 1.67-1.71 ppm (1H, double doublet), 2.25-2.39 ppm (7H, multiplet), 3.78-3.82 ppm (1H, double doublet)

### (4) Elemental Analysis (Metal Analysis: ICP-AES)

Mo content: 20.1 mass % (theoretical value: 20.2 mass %)

### [Example 9] Production of Compound No. 91

1.13 Grams (0.0045 mol) of molybdenum tetrachloride oxide and 19 ml of diethyl ether were loaded into a 100-milliliter three-necked flask under an Ar atmosphere, and were stirred at room temperature. A solution prepared from 1.33 g (0.018 mol) of tert-butyl alcohol, 14 ml of diethyl ether, and 11.4 ml (0.018 mol) of a n-butyl lithium-hexane solution was dropped thereinto under ice cooling. After the dropping, the temperature of the mixture was returned to room temperature, stirring was performed for 18 hours, and the solvent was exchanged with hexane, followed by filtration. The solvent was removed from the resultant filtrate, and 10 ml of diethyl ether was added. Next, 0.52 g (0.0045 mol) of 1-dimethylamino-2-methyl-2-propanol was dropped thereinto at room temperature, and stirring was performed for 18 hours. After that, the solvent was removed, and the residue was distilled at a bath temperature of 125° C. and a pressure of 54 Pa. Thus, Compound No. 91 was obtained as a reddish brown liquid. The yield was 0.25 g, and the percent yield was 12.5%.

### Analysis Values

### (1) Normal-Pressure TG-DTA

50% mass loss temperature: 210° C. (Ar flow rate: 100 ml/min., temperature increase at 10° C./min., sample amount: 10.387 mg)

### (2) Reduced-Pressure TG-DTA

50% mass loss temperature: 146° C. (10 Torr, Ar flow rate: 50 ml/min., temperature increase at 10° C./min., sample amount: 10.235 mg)

### (3) ¹H-NMR (Deuterated Benzene)

1.280 ppm (6H, singlet), 1.492 ppm (27H, singlet), 2.331 ppm (2H, singlet), 2.354 ppm (6H, singlet)

### (4) Elemental Analysis (Metal Analysis: ICP-AES)

Mo content: 21.2 mass % (theoretical value: 21.44 mass %)

### [Example 10] Production of Compound No. 109

1.17 Grams (0.0046 mol) of molybdenum tetrachloride oxide and 20 ml of diethyl ether were loaded into a 100-milliliter three-necked flask under an Ar atmosphere, and were stirred at room temperature. A solution prepared from 1.37 g (0.0184 mol) of tert-butyl alcohol, 15 ml of diethyl ether, and 11.7 ml (0.0184 mol) of a n-butyl lithium-hexane solution was dropped thereinto under ice cooling. After the dropping, the temperature of the mixture was returned to room temperature, stirring was performed for 15 hours, and the solvent was exchanged with hexane, followed by filtration. The solvent was removed from the resultant filtrate, and 10 ml of diethyl ether was added. Next, 0.48 g (0.0046 mol) of 1-methoxy-2-methyl-2-propanol was dropped thereinto at room temperature, and stirring was performed for 17 hours. After that, the solvent was removed, and the residue was distilled at a bath temperature of 135° C. and a pressure of 70 Pa. Thus, Compound No. 109 was obtained as an orange solid. The yield was 0.18 g, and the percent yield was 9%.

### Analysis Values

### (1) Reduced-Pressure TG-DTA

50% mass loss temperature: 135° C. (10 Torr, Ar flow rate: 50 ml/min., temperature increase at 10° C./min., sample amount: 9.686 mg)

### (2) ¹H-NMR (Deuterated Benzene)

1.276 ppm (6H, singlet), 1.517 ppm (27H, singlet), 3.268 ppm (2H, singlet), 3.337 ppm (3H, singlet)

### (3) Elemental Analysis (Metal Analysis: ICP-AES)

Mo content: 22.3 mass % (theoretical value: 22.1 mass %)

### Evaluation Example

The compounds of the present invention obtained in Examples 1 to 10, and Comparative Compounds 1 and 2 described below were subjected to the following evaluations.

### (1) Thermal Stability Evaluation

The thermal decomposition start temperature of each of the compounds was measured with a DSC measuring device. It can be judged that the thermal decomposition of a compound having a high thermal decomposition start temperature hardly occurs, and hence the compound is preferred as a thin-film forming raw material. The results are shown in Table 1.

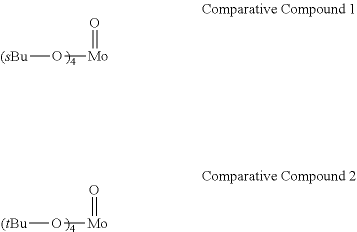

TABLE 1

| | | Thermal |
|---|---|---|
| | | decomposition start |
| | Compound | temperature [° C.] |
| Evaluation Example 1 | Compound No. 4 | 171 |
| Evaluation Example 2 | Compound No. 10 | 271 |
| Evaluation Example 3 | Compound No. 11 | 253 |
| Evaluation Example 4 | Compound No. 12 | 229 |
| Evaluation Example 5 | Compound No. 50 | 200 |
| Evaluation Example 6 | Compound No. 85 | 172 |
| Evaluation Example 7 | Compound No. 86 | 196 |
| Evaluation Example 8 | Compound No. 90 | 222 |
| Evaluation Example 9 | Compound No. 91 | 210 |
| Evaluation Example 10 | Compound No. 109 | 192 |
| Comparative | Comparative | 130 |
| Evaluation Example 1 | Compound 1 | |
| Comparative | Comparative | 130 |
| Evaluation Example 2 | Compound 2 | |

As shown in Table 1 above, while Comparative Compounds 1 and 2 each had a thermal decomposition start temperature of 130° C., the compounds of the present invention obtained in Examples 1 to 10 were each a compound having a thermal decomposition start temperature of 170° C. or more, and were hence each found to be a compound having high thermal stability. Of those, Compounds Nos. 10, 11, 12, 50, 86, 90, and 91 were each a compound having a thermal decomposition start temperature of 195° C. or more, and were hence each found to be a compound having higher thermal stability. Further, Compounds Nos. 10, 11, and 12 were each a compound having a thermal decomposition start temperature of 225° C. or more, and were hence each found to be a compound having much higher thermal stability. In particular, Compound No. 10 was a compound having a thermal decomposition start temperature of 270° C. or more, and was hence found to be a compound having particularly high thermal stability.

### Production of Thin-Film by ALD Method

A metal molybdenum thin-film was produced from each of the compounds of the present invention obtained in Examples 1 to 10 and Comparative Compounds 1 and 2 serving as a thin-film forming raw material on a silicon substrate with an apparatus illustrated in FIG. 1 by an ALD method under the following conditions. The measurement of the thickness of the resultant thin-film by an X-ray reflectivity method, the identification of the compound of the thin-film by an X-ray diffraction method, and the measurement of a carbon content in the thin-film by X-ray photoelectron spectroscopy were performed. The results are shown in Table 3.

### [Examples 11 to 20 and Comparative Examples 1 and 2] Production of Metal Molybdenum Thin-Film by ALD Method

### Conditions

Reaction temperature (substrate temperature): 250° C., reactive gas: hydrogen

### Steps

A series of steps consisting of the following steps (1) to (4) was defined as one cycle, and the cycle was repeated 50 times:
(1) a gas of the thin-film forming raw material obtained by vaporization under the conditions of a raw material vessel heating temperature of from 50° C. to 120° C. and a raw material vessel internal pressure of 100 Pa is introduced into a system, and deposition is performed at a system pressure of 100 Pa for 30 seconds (raw material introduction step and precursor thin-film formation step);
(2) an unreacted raw material is removed through argon purging for 10 seconds (evacuation step);
(3) the reactive gas is introduced into the system for a reaction at a system pressure of 100 Pa for 30 seconds (thin-film formation step); and
(4) the unreacted raw material is removed through argon purging for 10 seconds (evacuation step).

TABLE 2

| | Thin-film | Thick- | | |
|---|---|---|---|---|
| | forming | ness | Compound | |
| | raw | of thin- | of thin- | Carbon |
| | material | film | film | thin-film |
| Example 11 | Compound | 3.8 nm | Metal | Undetectable*¹ |
| | No. 4 | | molybdenum | |
| Example 12 | Compound | 5.6 nm | Metal | Undetectable*¹ |
| | No. 10 | | molybdenum | |
| Example 13 | Compound | 5.2 nm | Metal | Undetectable*¹ |
| | No. 11 | | molybdenum | |
| Example 14 | Compound | 5.0 nm | Metal | Undetectable*¹ |
| | No. 12 | | molybdenum | |
| Example 15 | Compound | 3.3 nm | Metal | Undetectable*¹ |
| | No. 50 | | molybdenum | |
| Example 16 | Compound | 3.5 nm | Metal | Undetectable*¹ |
| | No. 85 | | molybdenum | |
| Example 17 | Compound | 4.7 nm | Metal | Undetectable*¹ |
| | No. 86 | | molybdenum | |
| Example 18 | Compound | 4.1 nm | Metal | Undetectable*¹ |
| | No. 90 | | molybdenum | |
| Example 19 | Compound | 4.5 nm | Metal | Undetectable*¹ |
| | No. 91 | | molybdenum | |
| Example 20 | Compound | 3.7 nm | Metal | Undetectable*¹ |
| | No. 109 | | molybdenum | |
| Comparative | Comparative | 2.4 nm | Metal | 4 atm % |
| Example 1 | Compound 1 | | molybdenum | |
| Comparative | Comparative | 2.3 nm | Metal | 5 atm % |
| Example 2 | Compound 2 | | molybdenum | |

*¹The detection limit is 0.1 atm %.

It was recognized that while the carbon content in the metal molybdenum film obtained by the ALD method was 4 atm% or more in each of Comparative Examples 1 and 2, the carbon content in each of Examples 11 to 20 was less than 0.1 atm%, which was the detection limit. In other words, it was shown that the use of the compound of the present invention provided a high-quality thin-film. In addition, it was shown that while the thickness of the resultant thin-film was 2.4 nm or less in each of Comparative Examples 1 and 2, the thickness was 3.3 nm or more in each of Examples 11 to 20, and hence the use of the compound of the present invention provided a thin-film with high productivity. In each of Examples 12, 13, 14, 17, 18, and 19 out of those examples, the thickness of the resultant thin-film was 4.0 nm or more, and the metal molybdenum film was obtained with higher productivity. Further, in each of Examples 12, 13, and 14, the thickness of the resultant thin-film was 5.0 nm or more, and the metal molybdenum film was obtained with much higher productivity. In particular, in Example 12, the thickness of the resultant thin-film was 5.5 nm or more, and the metal molybdenum film was obtained with particularly high productivity.

It was shown from the foregoing that the compound of the present invention was excellent as a thin-film forming raw material because the compound had high thermal stability, and further, was able to produce a thin-film with high productivity when used as a thin-film forming raw material.

It was shown that each of Compounds Nos. 10, 11, 12, 86, 90, and 91 out of such compounds was more excellent as a thin-film forming raw material because the compound had high thermal stability, and further, was able to provide a thin-film with higher productivity when used as a thin-film forming raw material. Further, it was shown that each of Compounds Nos. 10, 11, and 12 was particularly excellent as a thin-film forming raw material because the compound had high thermal stability, and further, was able to provide a thin-film with particularly high productivity when used as a thin-film forming raw material. Further, it was shown that Compound No. 10 was the most excellent as a thin-film forming raw material because the compound had high thermal stability, and further, was able to provide a thin-film with the highest productivity when used as a thin-film forming raw material. In addition, it was shown that the thin-film forming raw material of the present invention was particularly suitable for the ALD method.

1. A thin-film forming raw material, comprising a molybdenum compound represented by the following general formula (1): 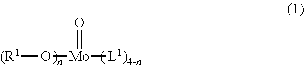
where R¹ represents an alkyl group having 1 to 5 carbon atoms or a fluorine atom-containing alkyl group having 1 to 5 carbon atoms, L¹ represents a group represented by the following general formula (L-1) or (L-2), and “n” represents an integer of from 1 to 4, provided that when “n” represents 4, R¹ represents a fluorine atom-containing alkyl group having 1 to 5 carbon atoms; 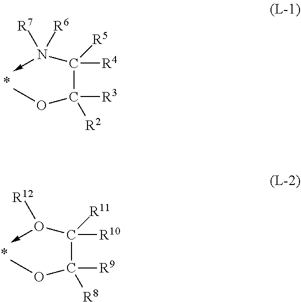
where R² to R¹² each independently represent a hydrogen atom, an alkyl group having 1 to 5 carbon atoms, or a fluorine atom-containing alkyl group having 1 to 5 carbon atoms, and * represents a bonding site.

2. The thin-film forming raw material according to claim 1, comprising the molybdenum compound in which “n” in the general formula (1) represents 4.

3. A method of producing a thin-film, comprising forming a thin-film containing a molybdenum atom on a surface of a substrate through use of the thin-film forming raw material of claim 1.

4. The method of producing the thin-film according to claim 3, comprising:
introducing a raw material gas obtained by vaporizing the thin-film forming raw material into a film formation chamber having the substrate set therein; and
subjecting the molybdenum compound represented by the general formula (1) in the raw material gas to decomposition and/or a chemical reaction, to thereby form the thin-film containing a molybdenum atom on the surface of the substrate.

5. The method of producing the thin-film according to claim 4,
wherein the method further comprises, between the raw material introduction and the thin-film formation, forming a precursor thin-film on the surface of the substrate through use of the thin-film forming raw material, and
wherein the thin-film formation includes causing the precursor thin-film to react with a reactive gas, to thereby form the thin-film containing a molybdenum atom on the surface of the substrate.

6. A molybdenum-containing thin-film, which is produced by using the thin-film forming raw material of claim 1.

7. A molybdenum compound, which is represented by the following general formula (2): 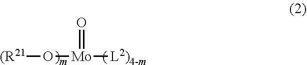
where R²¹ represents an alkyl group having 1 to 5 carbon atoms or a fluorine atom-containing alkyl group having 1 to 5 carbon atoms, L² represents a group represented by the following general formula (L-3) or (L-4), and “m” represents an integer of from 1 to 4, provided that when “m” represents 4, R²¹ represents a fluorine atom-containing alkyl group having 1 to 5 carbon atoms and having 1 to 8 fluorine atoms; 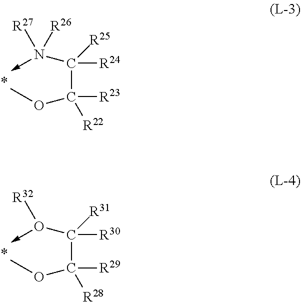
where R²² to R³² each independently represent a hydrogen atom, an alkyl group having 1 to 5 carbon atoms, or a fluorine atom-containing alkyl group having 1 to 5 carbon atoms, and * represents a bonding site.
